(19) United States
(12) Patent Application Publication
(10) Pub. No.: US 2004/0009424 A1
(43) Pub. Date: Jan. 15, 2004

(54) Protecting groups for lithographic resist compositions

(75) Inventors: Theodore H. Fedynyshyn, Sudbury, MA (US); Michael Sworin, Tyngsboro, MA (US); Roger Sinta, Woburn, MA (US)

Correspondence Address: NUTTER MCCLENNEN & FISH LLP, WORLD TRADE CENTER WEST, 155 SEAPORT BOULEVARD, BOSTON, MA, 02210-2604, US

(73) Assignee: MASS INSTITUTE OF TECHNOLOGY (MIT)

(21) Appl. No.: 10/377,422

(22) Filed: Feb. 28, 2003

Related U.S. Application Data
(60) Provisional application No. 60/360,972, filed on Mar. 1, 2002.

(51) Int. Cl. G03F 7/038; G03F 7/26

(52) U.S. Cl. 430/270.1; 430/311; 430/313

(57) ABSTRACT

The present invention provides acid labile protecting groups that can be utilized to protect one or more monomeric units of a polymeric constituent of a photoresist composition suitable for use in lithography. For example, in one embodiment, the acid labile protecting group is selected to be t-butoxymethyl which can be employed to protect, e.g., a hydroxystyrene or an acrylic acid moiety. The photoresist compositions of the invention can be utilized at any wavelength suitable for lithography, and particularly, at wavelengths below 248 nm, e.g., 157 nm.

### RELATED APPLICATION

The present application claims priority to a provisional patent application entitled “Protecting Groups for Lithographic Resist Compositions,” filed on Mar. 1, 2002, and having Application Serial No. 60/360,972. This provisional application is herein incorporated by reference.

The U.S. government has rights in this invention pursuant to a contract awarded by the Department of Defense, Contract No. F19628-00-C-0002.

### BACKGROUND

The present application relates generally to photoresist materials, and more particularly, to acid labile protecting groups that can be utilized to protect one or more monomeric units in polymeric constituents of photoresist compositions suitable for use in photolithography.

Photolithography employs photoresists, i.e., radiation sensitive resist materials, for transfer of images onto semiconductor wafers to selectively pattern the wafers for device manufacturing. For example, spin-on organic polymeric photoresists have enabled manufacturing of integrated circuits.

Recent advances in microlithographical techniques lay the foundation for performing lithography at sub-100 nm resolution. A wide variety of energy sources, such as X-rays, extreme ultra violet (EUV), low and high keV electrons, ion beams, and extended optical wavelengths, e.g., 157 nm, can potentially be employed for advanced sub-100 nm imaging. For example, lithography with 157 nm F₂ lasers represents the next evolutionary step in optical micro-lithography and has recently emerged as a promising candidate for the 100 nm and 70 nm lithographical applications.

The resist materials developed for longer wavelengths, however, are too absorbent to be useful as single layer resists at such low wavelengths, e.g., at 157 nm. For example, polyhydroxystyrene based resists, developed for 248 nm lithography, and polyacrylate and polycyclic copolymer based resists, developed for 193-nm lithography, are too absorbent to provide a single layer resist for use at 157 nm. A photoresist based on such polymers may be useful for 157 nm lithography only if the thickness of the resist is less than about 100 nm. This constraint on thickness can seriously compromise the resist's ability to perform its intended purpose. For example, such a resist may be too thin to withstand subsequent processing steps such as plasma etching and ion implantation.

Thus, a need exists for providing improved photoresist compositions for use in microlithography. More particularly, there is a need for photoresist compositions that exhibit enhanced sensitivity and plasma-etch selectivitiy. For example, a need exists for providing single layer photoresists for use at 157 nm.

### SUMMARY OF THE INVENTION

The present invention provides photoresists for use in lithography at a variety of wavelengths, for example, at wavelengths less than about 400 nm, such as 248, 193, and 157 nm. In one aspect, a photoresist composition of the invention includes a polymer having at least one monomeric unit with an acid labile group that has the following chemical formula:

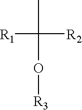

wherein

R₁ can be either a hydrogen, an alkyl group, or an aromatic group,

R₂ can be either a hydrogen, an alkyl group, or an aromatic group, and

R₃ can have the following chemical structure:

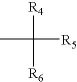

wherein

R₄ can be an alkyl, an alkenyl, an alkynyl, a cyclo-alkyl, a cyclo-alkenyl, an aromatic, a halogen, an alkoxy, or a cyano group,

R₅ can be an alkyl, an alkenyl, an alkynyl, a cyclo-alkyl, a cyclo-alkenyl, an aromatic, a halogen, an alkoxy, or a cyano group, and

R₆ can be an alkyl, an alkenyl, an alkynyl, a cyclo-alkyl, a cyclo-alkenyl, an aromatic, a halogen, an alkoxy, or a cyano group.

An example of an acid labile protecting group of the invention is t-butoxymethyl.

The term “acid labile protecting group” is known in the art and is intended to include a group that renders a moiety to which it is attached resistant to basic solutions but is removed under acidic conditions. Further, the term “alkyl group” is intended to encompass both unbranched and branched alkyl groups having 20 carbon atoms or less.

In a related aspect, the R₁ and R₂ moieties of the acid labile protecting group can be linked to form a cyclic structure. Further, any two of the R₄, R₅, and R₆ moieties can also be linked to form a cyclic structure.

In further aspects, the above acid labile protecting group can be attached to a moiety of a monomeric unit in a polymer according to the invention to generate a protected monomeric unit having the following general formula:

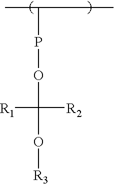

wherein P, which is a moiety attached to the polymer backbone, can be, for example, an aromatic group, a carbonyl group, a trifluoromethyl substituted alcohol, or a di-trifluoromethyl substituted alcohol.

In a related aspect, a photoresist composition of the invention includes a homopolymer having a chemical formula:

[-A-A-]n

wherein A is a monomeric unit having a moiety that is protected by an acid-labile protecting group according to the teachings of the invention. For example, A can be selected to be t-butoxymethyl-4-hydroxystyrene, t-butoxymethyl-3-hyrdoxystyrene, t-butoxymethyl-2-hydroxystyrene, t-butoxymethyl acrylate, t-butoxymethyl methacrylate, or t-butoxymethyl hexafluoroisopropanolstyrene.

In another aspect, the photoresist of the invention includes a co-polymer having the following chemical formula:

[-A-B-]n

wherein A is a monomeric unit having an acid labile protecting group according to the invention, such as those described above, and B is a different unprotected or protected monomeric unit. Some illustrative examples of B include, without limitation, hydroxystyrene (e.g., 2,3, or 4-hydroxystyrene), hexafluoroisopropanolethylene, hexafluoroisopropanolpropylene, methylhexafluoroisopropanolvinylalcohol, hexafluoroisopropanolstyrene, an acrylic acid, an acrylic ester, t-butoxymethyl-4-hydroxystyrene, t-butoxymethyl-3-hyrdoxystyrene, t-butoxymethyl-2-hydroxystyrene, t-butoxymethyl acrylate, t-butoxymethyl methacrylate, or t-butoxymethyl hexafluoroisopropanolstyrene.

The molar concentration of the monomeric unit A can be in a range of about 1 to about 90, or a range of about 5 to about 80, and preferably in a range of about 10 to about 50, and more preferably in a range of about 25 to about 50, and the molar concentration of the monomeric unit B can be in a range of about 10 to about 99, or a range of about 20 to about 95, and preferably in a range of about 50 to 90, and more preferably in a range of about 50 to about 75.

In another aspect, the invention provides a photoresist composition that includes a ter-polymer having the following chemical formula:

[-A-B—C-]n

wherein A is a momoneric unit having an acid labile protecting moiety according to the teachings of the invention, such as those described above, and B is a different unprotected or protected monomeric unit. C can be any monomeric unit that can polymerize with A and B, including A or B.

In addition to the polymers described above, a photoresist composition of the invention can also contain a small amount of base which may help to stabilize the polymer system. In general, less than 1% of the polymer composition is a base component, based on the total weight of the polymer composition, e.g., less than 0.5%. Suitable bases typically are organic bases known in the art such as tetrabutylammonium hyroxide, diazabicyclo[5.4.0]undec-7-ene, diphenyl amine, trioctyl amine, or triheptyl amine.

Further, a photoresist composition of the invention can include a photoacid generator. The term “photo-acid generator” is recognized in the art and is intended to include those compounds which generate acid in response to radiant energy. The choice of a photoacid generator for use in a composition of the invention depends in part on the the radiation wavelength to which the photoresist is exposed. For example, in some embodiment, preferred Photoacid generators are those that are reactive to deep UV radiation, e.g., to radiant energy having a wavelength equal to or less than 248 nm, and are preferably highly reactive to radiation at 157 nm.

The combination of the photo-acid generator and polymer should be soluble in an organic solvent. Preferably, the solution of the photo-acid generator and polymer in the organic solvent are suitable for spin coating. The photo-acid generator can include a plurality of photo-acid generators. The photo-acid generator is included in the composition at levels between about 0.01% and about 50%, more preferably between about 0.5% and about 20%, and most preferably between about 1.0% and about 10%, based on the total weight of the polymer composition.

Suitable photo-acid generators include onium salts, such as triphenylsulfonium salts, sulfonium salts, iodonium salts, diazonium salts and ammonium salts, 2,6-nitrobenzylesters, aromatic sulfonates, sulfosuccinimides and photosensitive organic halogen compounds as disclosed in Japanese Examined Patent Publication No. 23574/1979.

Examples of diphenyliodonium salts include diphenyliodonium triflate (DPI-105, Midori Kagaku Co. Ltd.) and diphenyliodonium tosylate (DPI-201, Midori Kagaku Co. Ltd.). Examples of suitable bis(4-tert-butylphenyl)iodonium salts include bis(4-tert-butylphenyl)iodonium triflate (BBI-105, Midori Kagaku Co. Ltd.), bis(4-tert-butylphenyl)iodonium camphorsulfate (BBI-106, Midori Kagaku Co. Ltd.), bis(4-tert-butylphenyl)iodonium perfluorbutylate (BBI-109, Midori Kagaku Co. Ltd.) and bis(4-tert-butylphenyl)iodonium tosylate (BBI-201, Midori Kagaku Co. Ltd.). Suitable examples of triphenylsulfonium salts include triphenylsulfonium hexafluorophosphate (TPS-102, Midori Kagaku Co. Ltd.), triphenylsulfonium triflate (TPS-105, Midori Kagaku Co. Ltd.) and triphenylsulfonium perfluorobutylate (TPS-109, Midori Kagaku Co. Ltd.). An example of an aromatic sulfonate is 1,2,3-tri(methanesulfonyloxy)benzene.

Specific examples of the photosensitive organic halogen compound include halogen-substituted paraffinic hydrocarbons such as carbon tetrabromide, iodoform, 1,2,3,4-tetrabromobutane and 1,1,2,2-tetrabromoethane; halogen-substituted cycloparaffinic hydrocarbons such as hexabromocyclohexane, hexachlorocyclohexane and hexabromocyclododecane; halogen-containing s-triazines such as tris(trichloromethyl)-s-triazine, tris(tribromomethyl)-s-triazine, tris(dibromomethyl)-s-triazine and 2,4-bis(tribromomethyl)-6-methoxyphenyl-s-triazine; halogen-containing benzenes such as (bis(trichloromethyl)benzene and bis(tribromomethyl)benzene; halogen-containing sulfone compounds such as tribromomethylphenylsulfone, trichloromethylphenylsulfone and 2,3-dibromosulforane; and halogen-substituted isocyanurates such as tris(2,3-dibromopropyl)isocyanurate. Among such photosensitive organic halogen compounds, a bromine-containing compound is preferred.

These and other aspects of the invention can be better understood by reference to the following detailed description and the appended claims.

### DETAILED DESCRIPTION

The present invention provides photoresists and methods for producing photoresists for use in photolithography at a variety of wavelengths, e.g., 157 nm. The photoresists of the invention have structures based on homopolymers, copolymers or terpolymers having at least one monomeric unit with an acid labile protecting group having the following chemical formula (1):

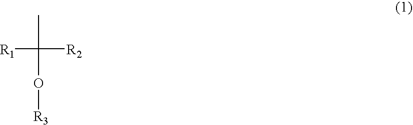

wherein

R₁ can be either a hydrogen, an alkyl group, or an aromatic group,

R₂ can be either a hydrogen, an alkyl group, or an aromatic group, and

R₃ can have the following chemical formula (2):

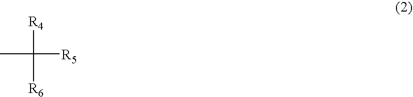

wherein

R₄ can be an alkyl, an alkenyl, an alkynyl, a cyclo-alkyl, a cyclo-alkenyl, an aromatic, a halogen, an alkoxy, or a cyano group,

R₅ can be an alkyl, an alkenyl, an alkynyl, a cyclo-alkyl, a cyclo-alkenyl, an aromatic, a halogen, an alkoxy, or a cyano group, and

R₆ can be an alkyl, an alkenyl, an alkynyl, a cyclo-alkyl, a cyclo-alkenyl, an aromatic, a halogen, an alkoxy, or a cyano group.

Further, in the chemical structures of an acid labile protecting group shown above, R₁ and R₂ can be bonded to form a cyclic structure shown by chemical formula (3) below:

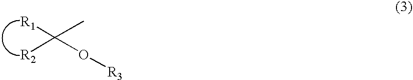

In addition, any two of the R₄, R₅, and R₆ groups in an acid labile protecting group according to the teachings of the invention can be linked to form a cyclic structure, such as structure defined by chemical formula (4) shown below:

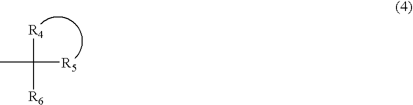

An acid labile protecting group can be attached to a variety of monomeric units in a polymeric constituent of a photoresist composition of the invention. In general, an acid labile protecting group of the invention can be attached to a monomeric unit having the following chemical formula (5) in a polymer forming a constituent of a photoresist composition of the invention:

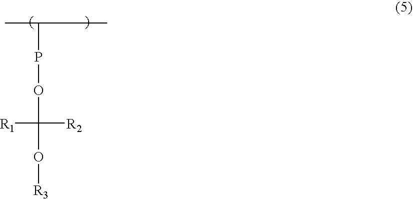

wherein P, which is a moiety attached to the polymer backbone, can be, for example, an aromatic group, a carbonyl group, a trifluoromethyl substituted alcohol, or a di-trifluoromethyl substituted alcohol.

A photoresist according to the invention can include a homopolymer, a copolymer or a terpolymer in which one monomeric unit is selected to be a 4-hydroxystyrene, a 3-hydroxystyrene, or a 2-hydroxystyrene having the following chemical formulas (6), (7) and (8), respectively:

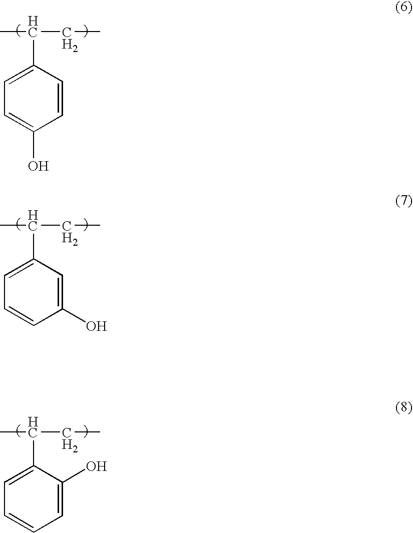

Further, a polymer in a photoresist of the invention can include a monomeric unit that is selected to be hexafluoroisopropanolpropylene, hexafluoroisopropanolethylene, or methylhexafluoroisopropanolvinylalcohol having the following chemical formulas (9), (10), and (11), respectively:

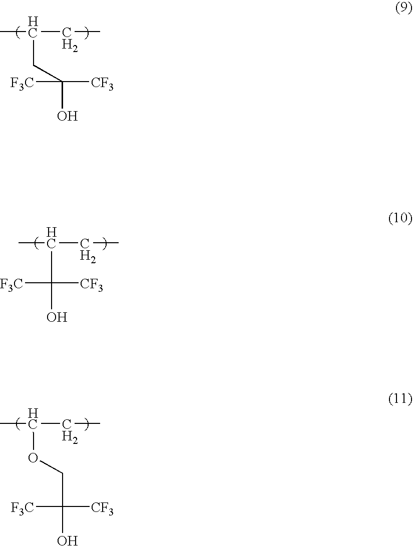

Other monomeric units suitable for use in a photoresist polymer of the invention can include, for example, hexafluoroisopropanolstyrene, acrylic acid, or acrylic ester having the following chemical formulas (12), (13) and (14), respectively:

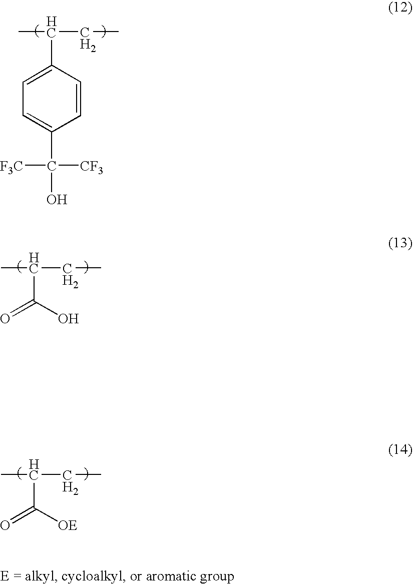

Other monomeric units suitable for use in a polymer of a photoresist composition of the invention include methyl-HFIP-substituted norbornene, methyl-HFIP-substituted norbornenol, methyl-HFIP-substituted norbornenemethanol, maleic anhydride, methyl-HFIP-substituted tetracyclododecene, methyl-HFIP-substituted tetracyclododecenol, ethylene, vinylidene fluoride, or tetrafluoroethylene having chemical formulas (15)-(23), respectively:

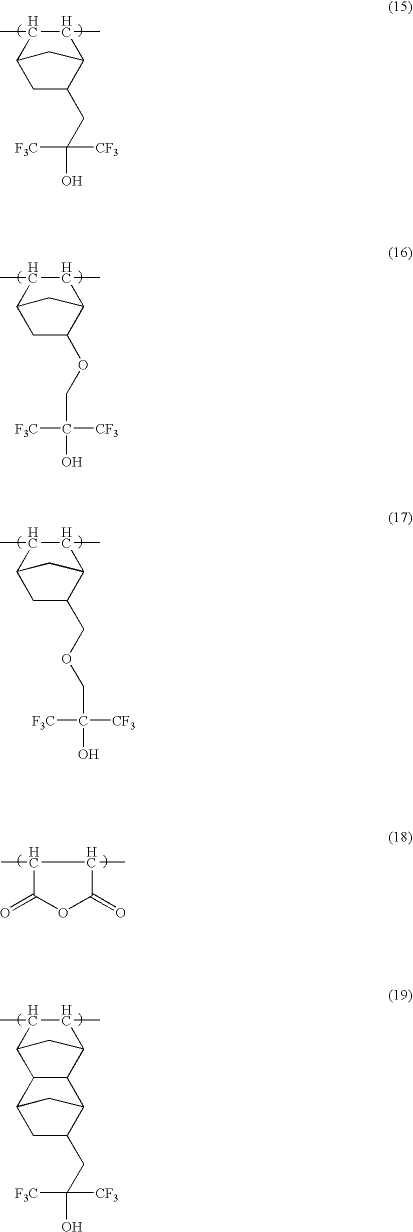

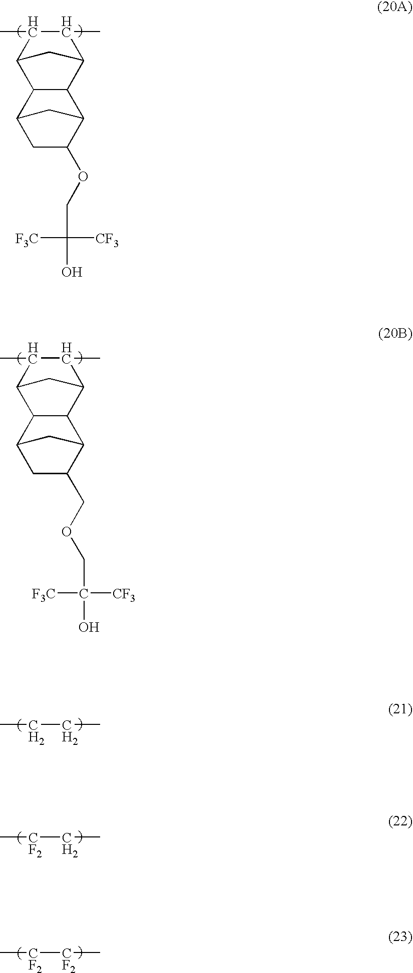

Further, the monomeric units recited above can be modified, e.g., halogenated, methylated, fluorinated, to generate additional monomeric units suitable for use in a polymeric constituent of a photoresist composition of the invention. By way of illustration, the chemical formulas (24)-(37) of some of these monomeric units are provided below:

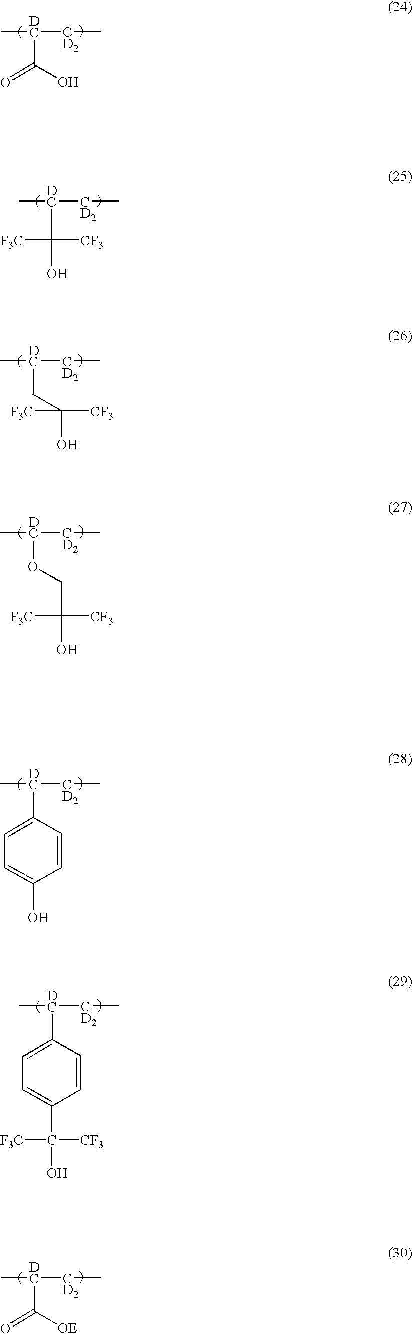

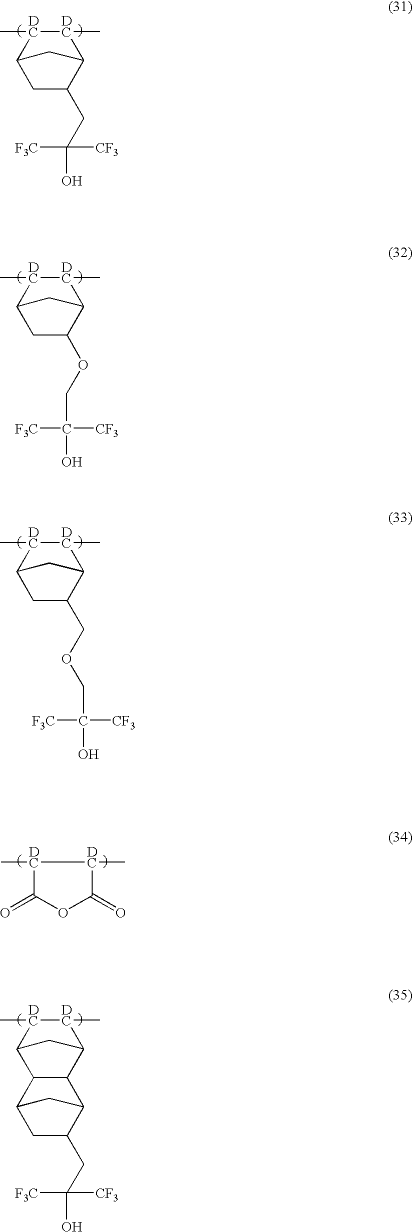

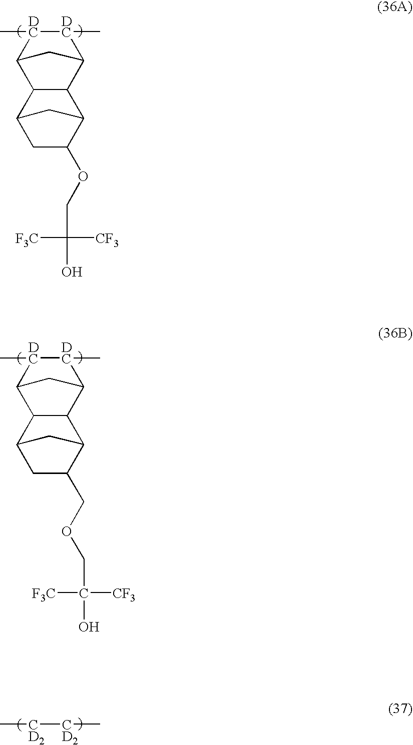

wherein E can be an alkyl, cycloalkyl, or an aromatic group, and D=H, F, Cl, Br, I, CN, CH₃, CF₃, and E

The above monomeric units can be polymerized with monomeric units having acid-labile protecting groups according to the teachings of the invention, such as the acid-labile protecting groups defined by the chemical formula (1) above, to provide co-polymers or ter-polymers suitable for use in a resist composition according to the invention.

By way of example, chemical formulas (38)-(48) of an illustrative set of monomeric units having an acid labile protecting group according to the invention are provided below:

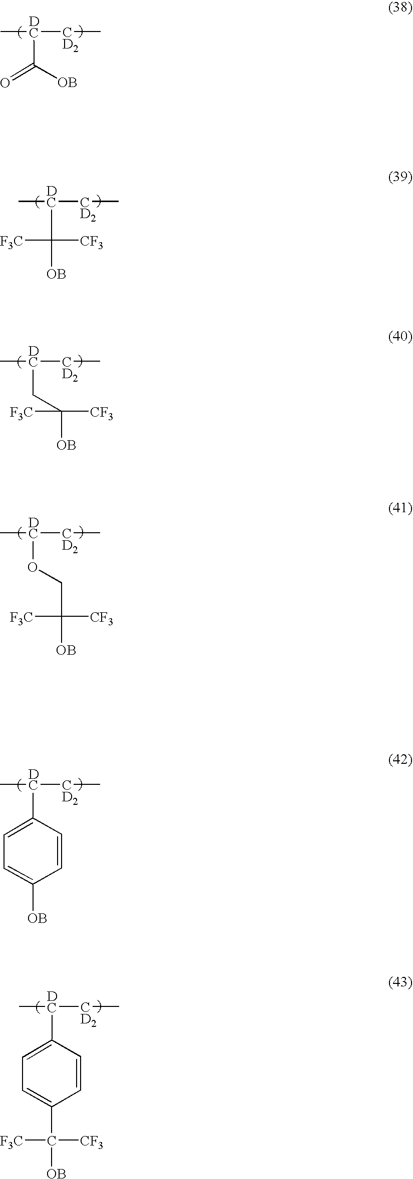

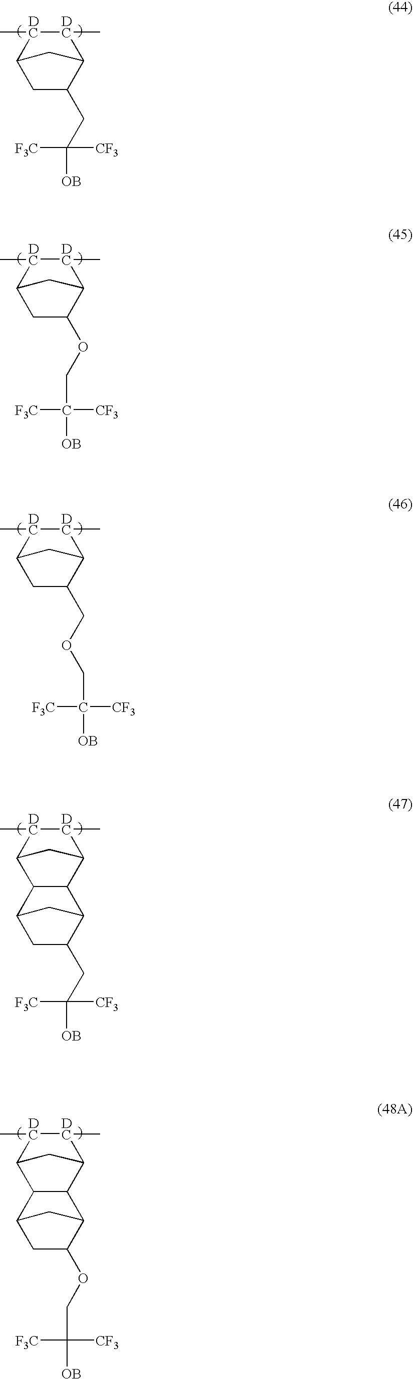

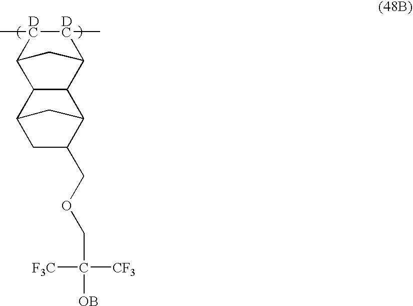

wherein E can be an alkyl, a cycloalkyl, or an aromatic group, and D=H, F, Cl, Br, I, CN, CH₃, CF₃, or E, and B denotes an acid-labile group in accord with the teachings of the invention having the above chemical formula (1).

In a preferred embodiment of the invention, the acid labile protecting group is selected to be a t-butoxymethyl moiety that is employed to protect a monomeric unit of a polymeric constituent of the photoresist composition. For example, the t-butoxymethyl moiety can be attached to hydroxystyrene to form a t-butoxymethylhydroxystyrene having chemical formula (49) shown below:

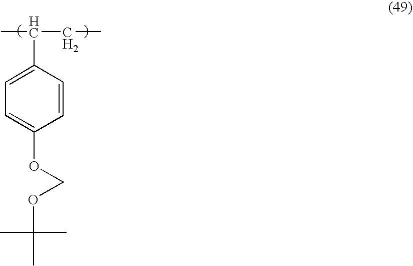

The t-butoxymethylhydroxystyrene can then be utilized as a monomeric unit to polymerize with any of the monomeric units described above in order to form a polymer suitable for use in a photoresist of the invention.

Alternatively, the t-butoxymethyl moiety can be employed to protect an acrylic acid or methacrylic acid to form t-butoxymethyl acrylate or t-butoxymethyl methacrylate having chemical formulas (50) and (51), respectively, shown below:

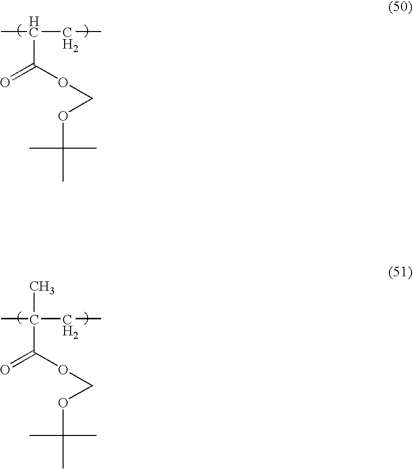

The protected acrylate and/or methacrylate groups can polymerize with other monomeric units, such as, acrylic acid or methacrylic acids, to form co-polymers or ter-polymers in a photoresist of the invention.

In one preferred embodiment, the t-butoxymethyl protecting group is utilized to form t-butoxymethyl hexafluoroisopropanolstyrene having the following chemical formula (52), which can be utilized in polymeric constituents of a photoresist composition of the invention:

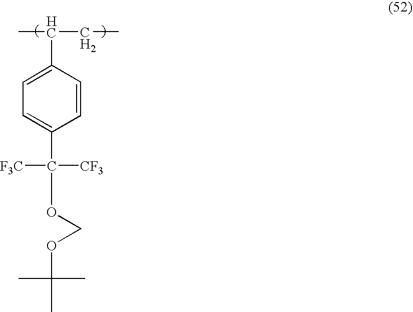

A photoresist composition of the invention can include polymers having monomeric units with acid labile protecting groups according to the invention, such as those described above, and a photoacid generator (PAG) that can be activated, for example, by exposure to actinic radiation, to generate acid. The acid causes removal of the acid labile protecting group, thereby rendering the exposed regions of the photoresist base soluble. The term “photo-acid generator” (PAG) is recognized in the art and is intended to include those compounds which generate acid in response to radiant energy. The PAG should respond to energies at one or more wavelengths and energies such as 248 nm, 193 nm, 157 nm, e-beam (high or low voltage e-beam), x-rays, EUV and/or ion beam. The photo-acid generator should be soluble in the polymer resin or solubilized in an organic solvent. Preferably, the solution of the photo-acid generator and polymer in the organic solvent are suitable for spin coating. The photo-acid generator can include a plurality of photo-acid generators. The photo-acid generator is included in the composition at levels between about 0.01% and about 50%, more preferably between about 0.5% and about 20%, and most preferably between about 1.0% and about 10%, based on the total weight of the photoresist composition.

Suitable photo-acid generators include onium salts, such as triphenylsulfonium salts, sulfonium salts, iodonium salts, diazonium salts and ammonium salts, 2,6-nitrobenzylesters, 1,2,3-tri(methanesulfonyloxy)benzene, sulfosuccinimides and photosensitive organic halogen compounds as disclosed in Japanese Examined Patent Publication No. 23574/1979.

Examples of diphenyliodonium salts include diphenyliodonium triflate (DPI-105, Midori Kagaku Co. Ltd.) and diphenyliodonium tosylate (DPI-201, Midori Kagaku Co. Ltd.). Examples of suitable bis(4-tert-butylphenyl)iodonium salts include bis(4-tert-butylphenyl)iodonium triflate (BBI-105, Midori Kagaku Co. Ltd.), bis(4-tert-butylphenyl)iodonium camphorsulfate (BBI-106, Midori Kagaku Co. Ltd.), bis(4-tert-butylphenyl)iodonium perfluorbutylate (BBI-109, Midori Kagaku Co. Ltd.) and bis(4-tert-butylphenyl)iodonium tosylate (BBI-201, Midori Kagaku Co. Ltd.). Suitable examples of triphenylsulfonium salts include triphenylsulfonium hexafluorophosphite (TPS-102, Midori Kagaku Co. Ltd.), triphenylsulfonium triflate (TPS-105, Midori Kagaku Co. Ltd.) and triphenylsulfonium perfluorobutylate (TPS-109, Midori Kagaku Co. Ltd.) Specific examples of the photosensitive organic halogen compound include halogen-substituted paraffinic hydrocarbons such as carbon tetrabromide, iodoform, 1,2,3,4-tetrabromobutane and 1,1,2,2-tetrabromoethane; halogen-substituted cycloparaffinic hydrocarbons such as hexabromocyclohexane, hexachlorocyclohexane and hexabromocyclododecane; halogen-containing s-triazines such as tris(trichloromethyl)-s-triazine, tris(tribromomethyl)-s-triazine, tris(dibromomethyl)-s-triazine and 2,4-bis(tribromomethyl)-6-methoxyphenyl-s-triazine; halogen-containing benzenes such as (bis(trichloromethyl)benzene and bis(tribromomethyl)benzene; halogen-containing sulfone compounds such as tribromomethylphenylsulfone, trichloromethylphenylsulfone and 2,3-dibromosulforane; and halogen-substituted isocyanurates such as tris(2,3-dibromopropyl)isocyanurate. Among such photosensitive organic halogen compounds, a bromine-containing compound is particularly preferred.

The photosensitive composition of the present invention can be used by dissolving the composition in a solvent. The solvent is not particularly limited, so long as it is a solvent capable of presenting adequate solubility to the resin, photo-acid-generating material and capable of providing good coating properties. For example, it may be a cellosolve type solvent such as methyl cellosolve, ethyl cellosolve, methyl cellosolve acetate or ethyl cellosolve acetate. Ethylene glycol based solvents such as ethylene glycol monomethyl ether, diethylene glycol monomethyl ether, diethylene glycol dibutyl ether, diethylene glycol and diethylene glycol dimethyl ether are suitable as organic solvents for the photosensitive compositions of the invention. Propylene glycol based solvents such as propylene glycol monoethyl ether, propylene glycol monobutyl ether, propylene glycol monomethyl ether acetate, dipropylene glycol dimethyl ether or propylene glycol monoethyl ether acetate can be used. Suitable ester type solvents include butyl acetate, amyl acetate, ethyl butyrate, butyl butyrate, diethyl oxalate, ethyl pyruvate, ethyl-2-hydroxybutyrate, 2-methyl-acetoacetate, methyl lactate or ethyl lactate. Alternatively, alcohols are utilized and include heptanol, hexanol, nonanol, diacetone alcohol or furfuryl alcohol. Examples of suitable ketone solvents include cyclohexanone or methylamyl ketone. Ethers useful as solvating agents include methyl phenyl ether or diethylene glycol dimethyl ether. Polar solvents, such as dimethylformamide or N-methylpyrrolidone can also be used. The solvents can be used alone or as combinations of two or more solvents.

Typically the solvent is used in an amount of from 1 to 100 times by weight, e.g., 5 to 30 times by weight, relative to the total amount of the solid content of the photosensitive composition.

Further, the photosensitive composition of the present invention may contain various additives such as a surfactant, a coating property-improving agent, a stabilizer, a colorant and an ultraviolet absorber, to such an extent not to impair the desired properties.

Suitable surfactants which can be added to the photosensitive composition to improve coating ability include nonionic surfactants including polyoxyethylene alkyl ethers such as polyoxyethylene lauryl ether, polyoxyethylene stearyl ether and polyoxyethylene oleyl ether, polyoxyethylene alkylphenyl ethers such as polyoxyethylene octylphenyl ether and polyoxyethylene nonylphenyl ethers. Suitable nonionic ester surfactants include polyethylene glycol dialkyl esters such as polyethylene glycol dilaurate and polyethylene glycol distearate. Alternatively, fluorine-containing surfactants can be utilized which contain a fluoroalkyl or perfluoroalkyl group such as Efftop EF301, EF303 and EF352 (manufactured by Shinakitakasei Co., Ltd.), Megafac F171, F172 and F173 (manufactured by Dainippon Ink Co., Ltd.), Asahiguard AG710 (manufactured by Asahi Glass Co., Ltd.), Fluorad FC430 and FC431 (manufactured by Sumitomo 3M Co., Ltd.), and Surflone S-382, SC101, SC102, SC103, SC104, SC105 and SC106 (manufactured by Asahi Glass Co., Ltd.). Organosiloxane surfactants, such as organosiloxane polymer KP341 (manufactured by Shinetsu Kagaku Kogyo Co., Ltd.) are also suitable for decreasing the surface tension of the solution containing the photosensitive composition. Additionally, acrylic acid- or methacrylic acid-type polymers and copolymers such as Polyflow No. 75, No. 95 and WS (manufactured by Kyoeisha Yushikagaku Kogyo Co., Ltd.); and the like are also suitable surfactants. The amount of the surfactant to be added is usually less than 2 parts by weight, preferably 0.005-1 part by weight, per 100 parts by weight of the abovementioned condensate.

Furthermore, antioxidants or defoaming agents can be compounded as required to the radiation-sensitive composition of this invention.

After coating, the solvent will usually be removed by drying, conveniently in the temperature range from 70° to 160° C.

The resist film is a photopolymer composition which, after drying, has high photosensitivity, is not subject to autocatalytic decomposition, and has very good adhesion to the substrate. Furthermore, the resist film has high transparency and sensitivity, even in the wavelength range of 157 nm, and has good thermal stability.

To produce relief structures the substrate is coated with the formulation of the present invention and is then exposed. The expression “exposure” will be understood as meaning not only exposure through a photomask that contains a predetermined pattern, for example a photographic transparency, but also exposure with a laser beam that is moved by computer control over the surface of the coated substrate to produce an image, irradiation with computer-controlled electron beams, as well as exposure with X-ray or UV radiation through an appropriate mask.

A photoresist of the invention can be utilized at any wavelength suitable for performing photolithograply. For example, exposure can be carried out with UV radiation, preferably in the wavelength range from about 100 to 400 nm, more particularly from 150 to 250 nm and, most preferably, at 157 nm. Further, EUV, x-ray, and electron beam can also be utilized. Various known sources of radiation can be used for exposure, typically including mercury high-pressure lamps and UV lasers and, preferably, excimer lasers. The process parameters such as exposure time and distance from the radiation source and radiation-sensitive layer will usually depend on the type of radiation-sensitive formulation and on the desired properties of the coating, and can be determined by the person having ordinary skill in the art by routine experimentation.

After exposure, the wafer can be heated or baked at about 50° to about 160° C. for a few seconds to a few minutes. Subsequently, the exposed areas of the photoresist are washed out with a developer. The choice of developer will depend on the type of photoresist, in particular on the nature of the binder employed or of the resultant photolysis products. The developer may comprise aqueous solutions of bases to which organic solvents or mixtures thereof may be added.

Particularly preferred developers are the aqueous alkaline solutions that typically include solutions of alkali metal silicates, alkali metal phosphates, alkali metal hydroxides and alkali metal carbonates, but preferably tetraalkylammonium hydroxide solutions such as tetramethylammonium hydroxide solution. To these solutions may be added minor amounts of wetting agents and/or organic solvents. Typical organic solvents that may be added to the developer fluids include cyclohexanone, 2-ethoxyethanol, toluene, acetone, isopropanol, ethanol, as well as mixtures of two or more of these solvents.

The application of the developer is preferably effected by immersing the coated and imagewise exposed substrate in the developer solution, by spraying the developer solution on to the substrate, or by repeatedly applying and spin-coating the developer on to the coated and imagewise exposed substrate.

Photoresist compositions of the invention can be utilized in a variety of applications. For example, these resists can be employed in processing and/or patterning a semiconductor surface. For example, in one aspect, the invention provides a method for patterning a semiconductor substrate by coating the substrate surface with a photoresist of the invention, such as those described above. Selected portions of the coated substrate are then exposed to an activating radiation to cause a chemical transformation in the exposed portions, and either the exposed or unexposed portions are removed. Subsequently, plasma-etching of the substrate surface can generate the desired pattern thereon.

The plasma-etching step in the above method can be replaced with any method suitable for generating a pattern on either the exposed or unexposed portion of the coated semiconductor surface. For example, the substrate surface can be exposed to an ion beam to implant a selected dose of an ion in those portions of the substrate from which the photoresist coating is removed.

A photoresist composition of the invention provides a number of advantages. For example, the photoresist composition of the invention exhibits enhanced plasma-etch selectivity. That is, the unexposed portions of the photoresist are more resistant to plasma-etching. Further, a photoresist composition of the invention exhibits higher sensitivity, for example, a faster rate of becoming base soluble upon exposure to actinic radiation. These advantageous properties are useful at any wavelength at which the photoresist composition is employed. For example, a photoresist of the invention can be utilized as a single layer sensitive resist having a thickness of about 100 nm to 150 nm for performing high resolution lithography. Traditional photoresist compositions are too absorbing at 157 nm to be useful as single layer resists with sufficient thickness. In particular, a high absorption at 157 nm limits the depth of light penetration into the resist, and hence prevents complete exposure of the bottom of the resist to radiation. Without complete exposure, the resist can not image. It is possible to form extremely thin resists in which the light can penetrate to the bottom of the resist. Such resists, however, can not withstand subsequent processing steps such as plasma etching and/or ion implantation.

In contrast, the photoresists of the invention can be formed as single layers having sufficient thickness to be suitable for lithography.

The following experimental section provides a number of examples of photoresist compositions of the invention and methods of their production to further elucidate the invention. It should be understood that the following examples are presented only for illustrative purposes, and are not intended to limit the scope of the invention.

Preparation of Monomers

### EXAMPLE 1

### Preparation of (4-Vinylphenyl)magnesium Bromide

The Grignard reagent was prepared by a modification of the procedure of Sekiya and Stille described in J. Am. Chem. Soc. 1981, 103, 5096, herein incorporated by reference. A crystal of iodine was added to a mixture of Mg turnings (7.30 g, 300.29 mmol) in anhydrous THF (200 mL), followed by the dropwise addition of a solution of p-bromostyrene (48.81 g, 266.65 mmol) in THF (50 mL), over 1 h. The reaction mixture became warm after about one quarter of the solution was added, and a water bath was used to keep the internal temperature between 25 to 30° C. The reaction mixture was then allowed to stir at room temperature for an additional 1 h.

### EXAMPLE 2

### Preparation of 1,1,1,3,3,3-Hexafluoro-2-(4-vinylphenyl)-2-propanol

The title compound was prepared by a modification of the procedure of Przybilla described in German Patent No. DE4207261 (Sep. 9, 1993), herein incorporated by reference. The (4-vinylphenyl)magnesium bromide solution of Example 1 was cooled to −40 to −30° C. using a dry ice/acetone bath, then hexafluoroacetone was introduced below the surface until an excess was achieved (weight added 62 g, 373.45 mmol). The reaction mixture was stirred in the cooling bath for 15 min, then placed in an ice-bath for an additional 15 min, and finally poured into cold 1N H₂SO₄ (1000 mL). The aqueous solution was extracted with ether, and the combined extracts were washed with brine, dried (Na₂SO₄), and concentrated to provide 101.60 g of a pale yellow oil. This material was purified by vacuum distillation to provide 52.43 g (73%) of a colorless oil: bp 55-6° C. (1.3 mm); ¹H NMR (CDCl₃) δ 7.69 (d, 2ArH), 7.50 (d, 2ArH), 6.75 (dd, CH═), 5.84 (dd, ═CHH), 5.36 (dd, ═CHH), 3.73 (s, OH), +9% THF.

### EXAMPLE 3

### Preparation of 1-(2,2,2-Trifluoro-1-methoxymethoxy-1-trifluoromethylethyl)-4-vinylbenzene

To a mixture of NaH (60% dispersion, 968 mg, 24.20 mmol), washed with pentane, and THF (50 mL) a solution of 1,1,1,3,3,3-hexafluoro-2-(4-vinylphenyl)-2-propanol (5.00 g, 18.51 mmol) in THF (10 mL) was slowly added. The reaction mixture was allowed to stir at room temperature for 1 h, then cooled to −78° C. using a dry ice/acetone bath followed by the addition of chloromethyl methyl ether (1.50 mL, 19.75 mmol) in THF (5 mL). The reaction mixture was allowed to slowly warm to room temperature overnight, quenched with H₂O, concentrated, and partitioned between ether/H₂O. The combined extracts were washed with saturated NaHCO₃, brine, dried (Na₂SO₄), and concentrated to provide a crude oil. This material was purified by Kugelrohr distillation (bp 65-9° C., 1.3 mm), followed by column chromatography on silica gel using 50:1 hexane/ethyl acetate to provide 1.96 g (34%) of a colorless oil; ¹H NMR (CDCl₃) δ 7.60 (d, 2ArH), 7.50 (d, 2ArH), 6.75 (dd, CH═), 5.85 (dd, ═CHH), 5.40 (dd, ═CHH), 4.85 (s, CH₂), 3.60 (s, Me).

### EXAMPLE 4

### Preparation of 1-[1-(tert-Butoxymethoxy)-2,2,2-trifluoro-1-trifluoromethylethyl]-4-vinylbenzene

A solution of 1,1,1,3,3,3-hexafluoro-2-(4-vinylphenyl)-2-propanol (9.00 g, 33.31 mmol) in THF (10 mL) was slowly added to a mixture of NaH (60% dispersion, 1.11 g, 27.75 mmol), washed with pentane, and THF (50 mL). The reaction mixture was allowed to stir at room temperature for 1 h, then cooled to −78° C. using a dry ice/acetone bath followed by the addition of tert-butyl chloromethyl ether (22.75 mmol, generated in situ in hexane, 12.50 mL). The tert-butyl chloromethyl ether was prepared by a modification of the procedure of Goff et al, described in an article published in the Journal of Organic Chemistry, 1986, 51, 4711, herein incorporated by reference. The reaction mixture was allowed to slowly warm to room temperature overnight, quenched with H₂O, concentrated, and partitioned between ether/H₂O. The combined extracts were washed with saturated NaHCO₃, brine, dried (Na₂SO₄), and concentrated to provide a crude oil. This material was purified by column chromatography on silica gel using 50:1 hexane/ethyl acetate to provide 3.25 g (41%) of a colorless oil; ¹H NMR (CDCl₃) δ 7.60 (d, 2ArH), 7.50 (d, 2ArH), 6.75 (dd, CH═), 5.80 (dd, ═CHH), 5.40 (dd, ═CHH), 4.90 (s, CH₂), 1.30 (s, tBu).

Preparation of Polymers

General Polymerization Experimental Conditions:

All polymers were synthesized by first dissolving the monomers in tetrahydrofuran (20% weight/volume), followed by bubbling nitrogen through the solution for 30 minutes. The initiator used was azoisobutyronitrile (1 mole percent) and after addition, the mixture was heated to reflux while maintaining a nitrogen blanket. After 18 hours, the mixture was concentrated by 50% and added to hexane to precipitate the polymer. The polymer was then filtered, washed with hexane and dried under vacuum at 60° C. for ˜18 hours. Typical yields were between 60 and 80%. Analysis of the polymers by gel permeation chromatography and nuclear magnetic resonance spectroscopy revealed undetectable quantities of unreacted monomer. A list of the polymers prepared is shown in the Table 1 below.

TABLE 1

| | | Molar |
|---|---|---|
| Polymer | Polymer Name | Ratio |
| 1 | poly(4-hexafluoroisopropanol styrene) | 100 |
| 2 | poly(methoxymethyl-4-hexafluoroisopropanol styrene) | 100 |
| 3 | poly(t-butoxymethyl-4-hexafluoroisopropanol styrene) | 100 |
| 4 | poly(4-hexafluoroisopropanol styrene-co- | 70:30 |
| | methoxymethyl-4-hexafluoroisopropanol styrene) | |
| 5 | poly(4-hexafluoroisopropanol styrene-co- | 60:40 |
| | methoxymethyl-4-hexafluoroisopropanol styrene) | |
| 6 | poly(4-hexafluoroisopropanol styrene-co-t- | 70:30 |
| | butoxymethyl-4-hexafluoroisopropanol styrene) | |
| 7 | poly(4-hexafluoroisopropanol styrene-co-t- | 60:40 |
| | butoxymethyl-4-hexafluoroisopropanol styrene) | |

General Absorbance Measurement Conditions:

Each calcium fluoride (CaF₂) substrate was cleaned by rinsing with acetone followed with a plasma clean in a helium/oxygen barrel etcher. After this procedure, polymer absorption determinations were performed by measuring the transmission of the CaF₂ both prior to and after coating with the polymer sample. The polymers were dissolved to about 5% weight to weight in either cyclohexanone or propylene glycol monomethyl ether acetate. The polymers were then spin cast onto transparent (CaF₂) substrates and post-apply baked at a temperature of 150° C. for 30 minutes in a vacuum oven. The absorbance contributions from the solvent appeared to be negligible. The polymer thickness was determined using a profilometer after spin-casting the polymer solution on a bare silicon wafer at the same rotational velocity that was used for the CaF₂ substrate. Typically, resist thicknesses in the 70 to 150 nm range were used which usually yielded transmission values at 157 nm between 10 and 60%. The absorption coefficient was determined by measuring the transmission of the polymer at three different thicknesses followed by calculating the optical density at that thickness. The absorption coefficient was then obtained by performing a linear regression least squares curve fit of the three thicknesses plus the origin as the fourth point.

### EXAMPLE 5

### Absorbance of Fluorine Containing Homopolymers Measured at 157-nm

The following polymers were prepared as described in the above general polymerization conditions and the absorbance at 157 nm was measured. It can bee seen that the incorporation of fluorine into the polymers as an hexafluoroisopropanol moiety lowers the 157-nm absorbance of the polymers to under 4.0 μm⁻¹. An absorbance of under 3.0 μm⁻¹ is considered a significant improvement in polymer absorbance. It can be seen that the incorporation of the t-butoxymethyl moiety gives rise to a lower polymer absorbance than the incorporation of the methoxymethyl moiety and thus represents an improvement in polymer absorbance.

The polymer molecular weight, glass transition temperature, and optical absorbance at 157-nm are shown in Table 2 below.

TABLE 2

| Polymer | Mw (×10⁻³) | Mn (×10⁻³) | Tg (° C.) | α₁₅₇ (μm⁻¹) |
|---|---|---|---|---|
| 1 | 26.3 | 16.1 | 129 | 3.44 |
| 2 | 16.2 | 14.9 | 69 | 2.60 |
| 3 | 16.2 | 10.5 | 63 | na |
| 4 | 26.9 | 17.4 | 117 | 3.27 |
| 5 | 25.5 | 16.6 | 107 | 3.08 |
| 6 | 26.3 | 15.5 | 106 | 3.16 |
| 7 | 26.3 | 15.0 | 98 | 2.82 |

General Lithography Process Conditions:

The post apply bake (PAB) was performed by placing the silicon wafer on a hot plate at the desired time and temperature. The post exposure bake (PEB) was performed by placing the silicon wafer on a hot plate at the desired time and temperature. Development was achieved by utilizing Shipley LLD-26W, a commercial resist developer. The clearing dose (E₀) is the lowest exposure dose required to remove all resist after development. It was determined by either fitting a line through all points containing less then 80% normalized film thickness as a function of dose and determining the intercept for zero remaining film thickness, or if no slope could be determined, by noting the lowest exposure dose for which no resist remained. The contrast (γ) was determined by fitting a line through all points containing less then 80% normalized film thickness as a function of the log of dose and determining the absolute value of the slope. The unexposed film thickness loss (UFTL) was determined by subtracting the film thickness of an unexposed portion of the resist after development from the film thickness of the resist prior to exposure.

The resolution was determined by exposing the resist through either a binary or phase shift chrome on quartz mask containing unequal pitch features of 3:1 and 1.5:1 starting at 200 nm and decreasing by 10 nm. The resolution was determined by noting the smallest feature that printed at the pitches of 3:1 and 1.5:1.

In the example, di-t-butylphenyl iodonium perfluorobutyl sulfonate (TBPI-PFBS) are used as photoacid generators (PAG) and tetrabutyl amonium hydroxide (TBAH) is used as a base additive.

### EXAMPLE 5

### Preparation of HFIP-Based Positive Acid Catalyzed Resists Imaged at 100 nm Thick

The resist was prepared by adding the polymer, PAG, and base in the amounts listed in Table 3 below to 1567 parts of ethyl lactate solvent to generate an approximately 6.0% weight of solids to total weight solution. In the example, di-t-butylphenyl iodonium perfluorobutyl sulfonate (TBPI-PFBS) are used as photoacid generators (PAG) and tetrabutyl amonium hydroxide (TBAH) is used as a base additive. The solution was rolled over night and filtered through a 0.2 μm filter.

TABLE 3

| Resist | Amount | Polymer | Amount | PAG | Amount | Base |
|---|---|---|---|---|---|---|
| 39 | 94 | 4 | 6 | TBPI-PFBS | 1.2 | TBAH |
| 40 | 94 | 5 | 6 | TBPI-PFBS | 1.2 | TBAH |
| 47 | 94 | 6 | 6 | TBPI-PFBS | 1.2 | TBAH |
| 48 | 94 | 7 | 6 | TBPI-PFBS | 1.2 | TBAH |

To determine E₀ and UFTL, the resist was spin cast to an approximately a 100 nm film on a HMDS vapor primed silicon wafer followed by a PAB of 130° C. for 60 seconds. The resist was exposed to 157 nm light at a series of different doses between 0 and 200 mJ/cm². After exposure, the wafer was PEB baked for 130° C. for 90 seconds. The wafer was then immersed in a surfactant containing 2.38% aqueous tetramethyl ammonium hydroxide solution for 15 seconds, removed and rinsed with DI water, and dried under a stream of nitrogen gas. The E₀ and UFTL were then determined and are reported below.

To determine resolution, the resist was spin cast to an approximately 100 m film on a HMDS vapor primed silicon wafer followed by a PAB of 130° C. for 60 seconds. The resist was exposed to 157 nm light through either a binary or phase shift chrome on quartz mask at a series of different doses and focuses. After exposure, the wafer was PEB baked for 140° C. for 60 seconds. The wafer was then immersed in a surfactant containing 2.38% aqueous tetramethyl ammonium hydroxide solution for 30 seconds, removed and rinsed with DI water, and dried under a stream of nitrogen gas. The resolution of 3:1 pitch features was determined and is reported in Table 4 below.

TABLE 4

| | | | | Binary | |
|---|---|---|---|---|---|
| | E₀ | UFTL | E_{size} | Resolution | Phase Shift |
| Resist | (mJ/cm²) | (nm) | (mJ/cm²) | (nm) | Resolution (nm) |
| 39 | 1.7 | 0.4 | 22.7 | 130 | 90 |
| 40 | 5.0 | 0.0 | not | not | not measured |
| | | | measured | measured | |
| 47 | 4.0 | 0.7 | 12.0 | 100 | 70 |
| 48 | 4.0 | 4.0 | 12.6 | 90 | 70 |

The resolution data indicates that the resists containing the t-butoxymethyl moiety have improved resolution relative to resists containing the methoxymethyl moiety. The level of sensitivity of resists that imaged has also improved and is of sufficient sensitivity to allow high levels of manufacturing throughput. The results show that the UFTL is low in all cases. The results also show that resists based on poly(4-hexafluoroisopropanol styrene-co-t-butoxymethyl-4-hexafluoroisopropanol styrene) can be used as high-resolution positive acid catalyzed resists at a 100-nm thickness in 157-nm based lithography.

### EXAMPLE 6

### Comparison of Plasma Etching of HFIP-Based Polymers

Plasma etching was performed on polymer films coated on 6-inch silicon wafers to a thickness of 150 to 200 nm. Thermal oxide (Oxide) etching was performed on a Lam Rainbow etcher for 60 seconds employing an etch gas mixture of 8 sccm of CF₄, 12 sccm of CHF₃, and 200 sccm of Ar, at a pressure of 350 mTorr, with an electrode power of 700 Watts, and a lower electrode temperature of −20° C. Selectivity to oxide is calculated by dividing the thermal silicon dioxide etch rate of 6.05 nm/second by the polymer etch rate. Polysilicon (Poly) etching was performed on a Lam TCP etcher for 60 seconds employing an etch gas mixture of 37.5 sccm of Cl₂, 13.5 sccm of HBr, 6 sccm of He, and 1.5 sccm of O₂, at a pressure of 10 mTorr, with a source power of 200 Watts, a plate power of 100 Watts, and a lower electrode temperature of 45° C. Selectivity to poly is calculated by dividing the amorphous silicon etch rate of 2.85 nm/second by the polymer etch rate.

The two polymers employed were Polymer 4 which is poly(4-hexafluoroisopropanol styrene-co-methoxymethyl-4-hexafluoroisopropanol styrene) and Polymer 6 which is poly(4-hexafluoroisopropanol styrene-co-t-butoxymethyl-4-hexafluoroisopropanol styrene). Both polymers had a 70:30 ratio of unprotected to protected 4-hexafluoroisopropanol styrene. The plasma etch rates and selectivities are shown in Table 5 below.

TABLE 5

| | Oxide Etch Rate | Poly Etch Rate | Oxide | Poly |
|---|---|---|---|---|
| Polymer | (nm/s) | (nm/s) | Selectivity | Selectivity |
| Polymer 4 | 1.110 | 0.718 | 5.5 | 4.0 |
| Polymer 6 | 0.892 | 0.625 | 6.8 | 4.6 |

The results show that with the above oxide etch conditions the Polymer 4 etch rate is 25% higher then the Polymer 6 etch rate. This results in an oxide selectivity that is higher for Polymer 6 then for Polymer 4. The results also show that with poly etch conditions that the Polymer 4 etch rate is 15% higher then the Polymer 6 etch rate. This results in a poly selectivity that is higher for Polymer 6 then for Polymer 4. Lower plasma etch rates and higher etch selectivities are advantageous in transferring the resist pattern from the resist to the underlying substrate by plasma etching.

### EXAMPLE 7

### Comparison of Thermal Decomposition of HFIP-Based Polymers

Thermalgravimetric analysis (TGA) data was obtained by employing a TA Instruments Hi-Res modulated TGA 2950 using Thermal Advantage data collection software at a heating rate of 20° C./min in N₂ and analyzed using Universal Analysis 2000 version 3.0G. Polymer samples were used as a neat power. Polymer samples with 5% camphorsulfonic acid (CSA) were prepared by thoroughly mixing 19 parts of polymer with 1 part of camphorsulfonic acid and then used as a neat power. The onset of thermal decomposition for Polymers 2 and 3 are listed Table 6 below. Also listed are the onset of thermal decomposition for Polymer 2 plus 5% CSA and Polymer 3 plus 5% CSA.

The results show that both the MOM and BOM protecting groups are thermally stable to over 300° C. in the absence of acid. The results also show that both the MOM and BOM protecting groups readily deprotect at temperatures under 100° C. in the presence of acid.

TABLE 6

| | Protecting | Thermal Decomposition |
|---|---|---|
| Polymer | Group | Onset (° C.) |
| Polymer 2 | MOM | 354 |
| Polymer 3 | BOM | 317 |
| Polymer 2 + 5% CSA | MOM | 82 |
| Polymer 3 + 5% CSA | BOM | 48 |

The normalized loss of either the methoxymethyl or t-butoxymethyl protecting group as a function of temperature in the presense of 5% CSA is shown in Table 7 below. The results show that the t-butoxymethyl protecting group has a higher acid liability than the methoxymethyl protecting group at different temperatures as shown by the higher normalized loss of the t-butoxymethyl. No deprotection occures at 50° C. for either polymer. At 75° C., the polymer with the t-butoxymethyl protecting group has lost 80% of the protecting group while no loss of protecting group is observed for the polymer with the methoxymethyl protecting group. At 100° C. the polymer with the t-butoxymethyl protecting group has lost 100% of the protecting group while only 25% of the protecting group is lost for the polymer with the methoxymethyl protecting group. This behavior will translate higher sensitivity resist for polymers based on the t-butoxymethyl protecting group relative to polymers based on the methoxymethyl protecting group. The higher sensitivity is an improvement and advantage for resists in that it directly translates into higher manufacturing throughput.

TABLE 7

| | Polymer 2 + 5% CSA | Polymer 3 + 5% CSA |
|---|---|---|
| | (Normalized Protecting | (Normalized Protecting |
| Temperature | Group Remaining) | Group Remaining |
| 25 | 1.00 | 1.00 |
| 50 | 1.00 | 1.00 |
| 75 | 1.00 | 0.20 |
| 100 | 0.75 | 0.00 |
| 125 | 0.00 | 0.00 |
| 150 | 0.00 | 0.00 |

Those of ordinary skill in the art will know, or be able to ascertain, using no more than routing experimentation, many equivalents to the specific embodiments of the invention described above. These and all other equivalents are intended to be encompassed by the following claims. All publications and references cited herein are expressly incorporated herein by reference in their entirety.

What is claimed is:

1. A photoresist composition for use in lithography comprising:
a polymer having at least one monomeric unit with an acid labile protecting group having the following chemical formula: 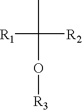
wherein
R₁ can be either a hydrogen, an alkyl group, or an aromatic group,
R₂ can be either a hydrogen, an alkyl group, or an aromatic group, and
R₃ can have the following chemical formula: 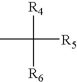
wherein
R₄ can be an alkyl, an alkenyl, an alkynyl, a cyclo-alkyl, a cyclo-alkenyl, an aromatic, a halogen, an alkoxy, or a cyano group,
R₅ can be an alkyl, an alkenyl, an alkynyl, a cyclo-alkyl, a cyclo-alkenyl, an aromatic, a halogen, an alkoxy, or a cyano group, and
R₆ can be an alkyl, an alkenyl, an alkynyl, a cyclo-alkyl, a cyclo-alkenyl, an aromatic, a halogen, an alkoxy, or a cyano group.

2. The photoresist composition of claim 1, wherein the R₁ and R₂ groups in said acid labile protecting group are linked to form a cyclic structure.

3. The photoresist composition of claim 1, wherein any two of the R₄, R₅ and R₆ groups in said acid labile protecting group are linked to form a cyclic structure.

4. The photoresist composition of claim 1, wherein the acid labile protecting group comprises a t-butoxymethyl moiety.

5. The photoresist composition of claim 1, wherein the protected monomeric unit of said polymer comprises a protected moiety having the following chemical formula: 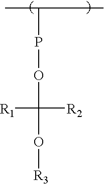
wherein P can be any of an aromatic group, a carbonyl group, a trifluoromethyl substituted alcohol, or a di-trifluoromethyl substituted alcohol.

6. The photoresist of claim 5, wherein said polymer is a homopolymer having a chemical formula:
[-A-A-]n
wherein A is a protected monomeric unit having said protected moiety.

7. The photoresist of claim 6, wherein said A can be any of t-butoxymethyl-4-hydroxystyrene, t-butoxymethyl-3-hydroxystyrene, t-butoxymethyl-2-hydroxystyrene, t-butoxymethyl acrylate, t-butoxymethyl methacrylate, or t-butoxymethyl hexafluoroisopropanolstyrene.

8. The photoresist of claim 5, wherein said polymer is a copolymer having a chemical formula:
[-A-B-]n
wherein A is a protected monomeric unit having said protected moiety and B a different protected or an unprotected monomeric unit.

9. The photoresist composition of claim 8, wherein B can be any of hydroxystyrene, hexafluoroisopropanolethylene, hexafluoroisopropanolpropylene, methylhexafluoroisopropanolvinylalcohol, hexafluoroisopropanolstyrene, an acrylic acid an acrylic ester, t-butoxymethyl-4-hydroxystyrene, t-butoxymethyl-3-hyrdroxystyrene, t-butoxymethyl-2-hydroxystyrene, t-butoxymethyl acrylate, t-butoxymethyl methacrylate, or t-butoxymethyl hexafluoroisopropanolstyrene.

10. The photoresist of claim 9, wherein A can be any of t-butoxymethyl-4-hydroxystyrene, t-butoxymethyl-3-hydroxystyrene, t-butoxymethyl-2-hydroxystyrene, t-butoxymethyl acrylate, t-butoxymethyl methacrylate, t-butoxymethyl hexafluoroisopropanolstyrene.

11. The photoresist of claim 5, wherein said polymer is a ter-polymer having a chemical formula:
[-A-B—C-]n
wherein A is a protected monomeric unit having said protected moiety, B is a different protected or unprotected monomeric unit, and C is a monomeric unit polymerizable with A and B.

12. The photoresist of claim 11, wherein A can be any of t-butoxymethyl-4-hydroxystyrene, t-butoxymethyl-3-hydroxystyrene, t-butoxymethyl-2-hydroxystyrene, t-butoxymethyl acrylate or t-butoxymethyl methacrylate, or t-butoxymethyl hexafluoroisopropanolstyrene.

13. The photoresist of claim 12, wherein B can be any of hydroxystyrene, hexafluoroisopropanolethylene, hexafluoroisopropanolpropylene, methylhexafluoroisopropanolvinylalcohol, hexafluoroisopropanolstyrene, an acrylic acid an acrylic ester, t-butoxymethyl-4-hydroxystyrene, t-butoxymethyl-3-hydroxystyrene, t-butoxymethyl-2-hydroxystyrene, t-butoxymethyl acrylate or t-butoxymethyl methacrylate, t-butoxymethyl hexafluoroisopropanolstyrene.

14. The photoresist of claim composition 1, further comprising a photoacid generator.

15. A composition of matter comprising t-butoxymethyl acrylate.

16. A composition of matter comprising t-butoxymethyl methacrylate.

17. A composition of matter comprising t-butoxymethyl hexafluoroisopropanolstyrene.

18. A composition of matter comprising t-butoxymethyl hydroxystyrene.

19. A method of processing a substrate, comprising:
coating the substrate with a photoresist composition comprising a polymer having at least one monomeric unit with an acid labile protecting group having the following chemical formula: 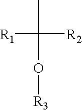
wherein
R₁ can be either a hydrogen, an alkyl group, or an aromatic group,
R₂ can be either a hydrogen, an alkyl group, or an aromatic group, and
R₃ can have the following chemical formula: 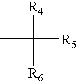
wherein
R₄ can be an alkyl, an alkenyl, an alkynyl, a cyclo-alkyl, a cyclo-alkenyl, an aromatic, a halogen, an alkoxy, or a cyano group,
R₅ can be an alkyl, an alkenyl, an alkynyl, a cyclo-alkyl, a cyclo-alkenyl, an aromatic, a halogen, an alkoxy, or a cyano group, and
R₆ can be an alkyl, an alkenyl, an alkynyl, a cyclo-alkyl, a cyclo-alkenyl, an aromatic, a halogen, an alkoxy, or a cyano group, and
exposing selected portions of the coated surface to an activating radiation to cause a chemical transformation in the exposed portions.

20. The method of claim 19, further comprising removing either the radiation-exposed or unexposed portions of the photoresist composition.

21. The method of claim 20, further comprising plasma-etching the substrate to generate a pattern thereon.

22. The method claim 20, further comprising exposing the substrate surface to an ion beam to implant a selected dose of the ion in the portions of the substrate from which the photoresist coating is removed.
